(19) United States
(12) Patent Application Publication
(10) Pub. No.: US 2016/0179596 A1
(43) Pub. Date: Jun. 23, 2016

(54) OPERATING METHOD OF DATA STORAGE DEVICE

(71) Applicant: SK hynix Inc., Gyeonggi-do (KR)

(72) Inventor: Young Gyun KIM, Gyeonggi-do (KR)

(21) Appl. No.: 14/638,716

(22) Filed: Mar. 4, 2015

(30) Foreign Application Priority Data
Dec. 17, 2014 (KR) 10-2014-0182181

(51) Int. Cl. G06F 11/07; G11C 29/42; G06F 11/263; G11C 29/56

(52) U.S. Cl. CPC G06F 11/076; G11C 29/56004; G11C 29/42; G06F 11/263

(57) ABSTRACT

An operating method of a data storage device includes selecting a memory block including a page in which an uncorrectable error occurs in a read operation, testing whether the selected memory block corresponds to a failure, including the selected memory block in a free block table when the selected memory block corresponds to a success as a result of the testing, and including the selected memory block when the selected memory block corresponds to the failure as a result of the testing.

### CROSS-REFERENCES TO RELATED APPLICATION

The present application claims priority under 35 U.S.C. §119(a) to Korean application number 10-2014-0182181, filed on Dec. 17, 2014, in the Korean Intellectual Property Office, which is incorporated herein by reference in its entirety.

### BACKGROUND

1. Technical Field

Various embodiments generally relate to a data storage device, and more particularly, to an operating method of a data storage device that manages a memory block in which a read failure has occurred, that is, a memory block having data that fails to be read.

2. Related Art

The paradigm for the computing environment has shifted to ubiquitous computing, so that computer systems can be used anytime and anywhere. The use of portable electronic devices such as mobile phones, digital cameras, and notebook computers has rapidly increased. In general, such portable electronic devices use a data storage device that has a memory device. The data storage device is used as a main memory device or an auxiliary memory device in the portable electronic devices.

Data storage devices that use a memory device provide excellent stability and durability, high information access speed, and low power consumption, since there are no moving parts. Data storage devices having such advantages include universal serial bus (USB) memory devices, memory cards having various interfaces, universal flash storage (UFS) devices, and solid state drives (SSD).

A memory device may include a plurality of memory cells for storing data. The data stored in the memory cells may be influenced by interference among the memory cells and be sensed incorrectly. Otherwise, the data stored in the memory cells may be changed by disturbance among the memory cells. For instance, the data stored in the memory cells may be changed by wear of the memory cells due to repetitive erase/program operations. In both cases, when the data stored in memory cells is inadvertently changed or inadvertently sensed as having changed, which could be due to various factors, the data stored in the memory cells may include an error.

If an error included in data is beyond the read correction capability of the data storage device, the read operation of the data storage device may fail. That is to say, if the error included in data is not corrected, a read failure may occur. The data storage device may manage memory cells with read failures, a page that includes such memory cells, or a memory block that includes such a page, such that read failures do not recur.

### SUMMARY

Various embodiments are directed to an operating method of a data storage device that manages a memory block in which a read failure has occurred.

In an embodiment, an operating method of a data storage device may include selecting a memory block including a page in which an uncorrectable error occurs in a read operation testing whether the selected memory block corresponds to a failure including the selected memory block in a free block table when the selected memory block corresponds to a success as a result of the testing, and including the selected memory block in a bad block table when the selected memory block corresponds to the failure as a result of the testing.

In an embodiment, an operating method of a data storage device may include determining whether an error is correctable when the error is detected in data read from a read-requested page, selecting a memory block which includes the page, when it is determined that the error is uncorrectable, and managing reservation information for the selected memory block, and reserving a test for the selected memory block.

According to the embodiments, read failures of data storage device may decrease and, due to this fact, the reliability of the data storage devices may improve.

### BRIEF DESCRIPTION OF THE DRAWINGS

FIG. 1 is a block diagram illustrating a data storage device in accordance with an embodiment.

FIG. 2 is a diagram to assist in the explanation of a memory block managing operation performed by a memory block managing block shown in FIG. 1.

FIG. 3 is a flow chart to assist in the explanation of the operations of the data storage device which performs the memory block managing operation in accordance with an embodiment.

FIG. 4 is a flow chart to assist in the explanation of the operations of the data storage device which performs the memory block managing operation in accordance with another embodiment.

FIG. 5 is a flow chart to assist in the explanation of a memory block testing operation shown in FIGS. 3 and 4.

FIG. 6 is a block diagram illustrating a data processing system including a data storage device in accordance an embodiment.

FIG. 7 is a block diagram illustrating a data processing system including a solid state drive (SSD) in accordance with an embodiment.

FIG. 8 is a block diagram illustrating an example of the SSD controller shown in FIG. 7.

FIG. 9 is a block diagram illustrating a computer system in which a data storage device is mounted, in accordance with an embodiment.

### DETAILED DESCRIPTION

In the present invention, advantages, features and methods for achieving them will become more apparent after a reading of the following exemplary embodiments taken in conjunction with the drawings. The present invention may, however, be embodied in different forms and should not be construed as limited to the embodiments set forth herein. Rather, these embodiments are provided to describe the present invention in detail to the extent that a person skilled in the art to which the invention pertains can easily enforce the technical concepts of the present invention.

It is to be understood herein that embodiments of the present invention are not limited to the particulars shown in the drawings, the drawings are not necessarily to scale and in some instances proportions may have been exaggerated to clearly depict certain features of the invention. While particular terminology is used, it is to be appreciated that the terminology used is for describing particular embodiments only and is not intended to limit the scope of the present invention.

As used herein, the term “and/or” includes any and all combinations of one or more of the associated listed items. It will be understood that when an element is referred to as being “on,” “connected to” or “coupled to” another element, it may be directly on, connected or coupled to the other element or Intervening elements may be present. As used herein, a singular form is intended to include plural forms as well, unless the context clearly indicates otherwise. It will be further understood that the terms “includes” and/or “Including,” when used in this specification, specify the presence of at least one stated feature, step, operation, and/or element, but do not preclude the presence or addition of one or more other features, steps, operations, and/or elements thereof.

Hereinafter, an operating method of a data storage device will be described below with reference to the accompanying drawings through various embodiments.

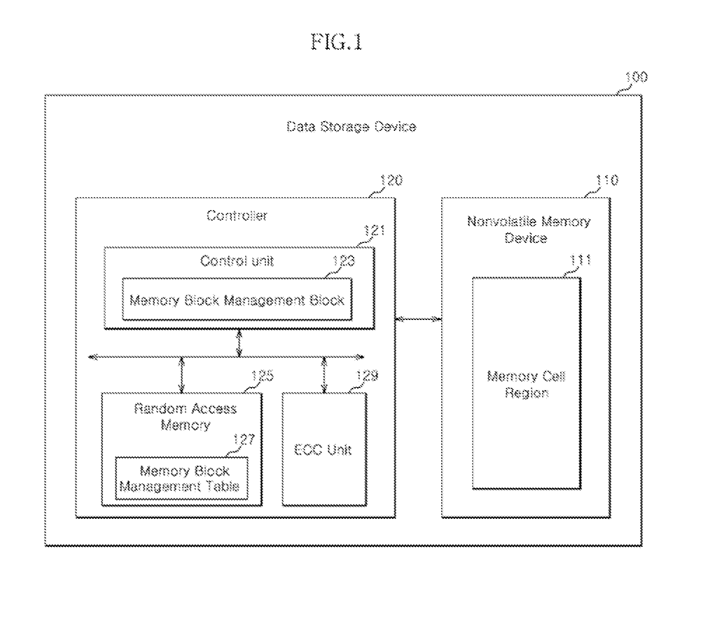

FIG. 1 is a block diagram illustrating a data storage device in accordance with an embodiment. A data storage device 100 may store data to be accessed by a host device (not shown) such as a mobile phone, an MP3 player, a laptop computer, a desktop computer, a game player, a TV, an in-vehicle infotainment system, and so forth. The data storage device 100 may also be referred to as a memory system.

The data storage device 100 may be manufactured as any one of various kinds of storage devices depending on the protocol of an interface which electrically couples the data storage device 100 with the host device. For example, the data storage device 100 may be configured as any one of various kinds of storage devices such as a solid state drive, a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a personal computer memory card international association (PCMCIA) card, a peripheral component interconnection (PCI) card, a PCI express (PCI-E) card, a compact flash (CF) card, a smart media card, a memory stick, and so forth.

The data storage device 100 may be manufactured as any one of various kinds of package types. For example, the data storage device 100 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP) and a wafer-level stack package (WSP).

The data storage device 100 may include a nonvolatile memory device 110. The nonvolatile memory device 110 may operate as the storage medium of the data storage device 100. The nonvolatile memory device 110 may be configured by any one of various types of nonvolatile memory devices such as a NAND flash memory device, a NOR flash memory device, a ferroelectric random access memory (FRAM) using a ferroelectric capacitor, a magnetoresistive random access memory (MRAM) using a tunneling magnetoresistance (TMR) layer, a phase change random access memory (PRAM) using a chalcogenide alloy, and a resistive random access memory (ReRAM) using a transition metal oxide, depending on the type of memory cells which make-up the memory cell region 111.

The data storage device 100 may include a controller 120. The controller 120 may include a control unit 121, a random access memory 125, and an error correction code (ECC) unit 129.

The control unit 121 may control the general operations of the controller 120. The control unit 121 may analyze and process a signal which is inputted from the host device. To this end, the control unit 121 may decode and drive the firmware or software loaded on the random access memory 125. The control unit 121 may be realized through hardware or hardware combination of hardware and software.

The control unit 121 may include a memory block management block 123 for processing the failure of a read operation (hereinafter, referred to as a read failure) for the nonvolatile memory device 110. The memory block management block 123 may be realized in the form of hardware or in the form of firmware or software, which may be decoded and driven by the control unit 121.

The random access memory 125 may store firmware or software to be driven by the control unit 121. Also, the random access memory 125 may store data necessary for the driving of the firmware or the software, for example, metadata such as a memory block management table 127. That is to say, the random access memory 125 may operate as the working memory of the control unit 121.

The random access memory 125 may be configured to temporarily store data to be transmitted from the host device to the nonvolatile memory device 110 or from the nonvolatile memory device 110 to the host device. In other words, the random access memory 125 may operate as a data buffer memory or a data cache memory.

The ECC unit 129 may perform an error detecting operation for detecting whether an error is included in the data read from the nonvolatile memory device 110 and an error correcting operation for removing the error included in the data. To this end, the ECC unit 129 may generate error correction codes for data to be stored in the nonvolatile memory device 110. The ECC unit 129 may detect errors of data read from the nonvolatile memory device 110, based on the error correction codes.

When an error within the error correction capability is detected, the ECC unit 129 may correct the detected error. When the detected error is corrected (that is, when an ECC succeeds), a read failure of the nonvolatile memory device 110 does not occur. Namely, when the detected error is corrected, the read operation of the data storage device 100 succeeds. When where an error beyond the error correction capacity is detected, the ECC unit 129 may not correct the detected error. When the detected error is not corrected (that is, in an ECC failure), a read failure for the nonvolatile memory device 110 may occur.

When a read failure has occurred in a memory block, the memory block management block 123 of the control unit 121 may perform a test operation for the memory block, to determine whether a read failure has temporarily occurred. The memory block management block 123 may manage (or process) the memory block, based on a test result. When a read failure has occurred, the memory block management block 123 may perform a test operation in real time, or may defer the test operation such that the test operation may be performed at an idle time.

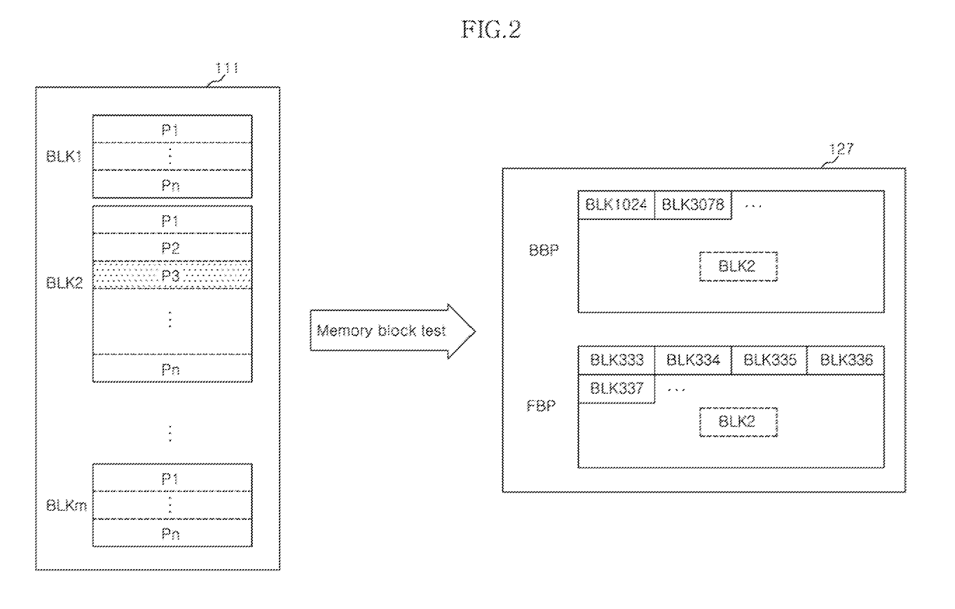

FIG. 2 is a diagram to assist in the explanation of a memory block managing operation performed by a memory block managing block shown in FIG. 1.

The memory cell region 111 may include memory blocks BLK1 to BLKm. Each of the memory blocks BLK1 to BLKm may include pages P1 to Pn. The memory cells constituting the memory cell region 111 may simultaneously operate due to physical or structural reasons. For instance, some memory cells may be simultaneously be read and programmed (or written). The set of memory cells to be simultaneously read and programmed or the unit of read and program operations may be a page P. In another instance, some memory cells may be simultaneously erased. The set of memory cells to be simultaneously erased or the unit of an erase operation may be referred to as a memory block BLK.

An example is used in which an error beyond the error correction capability of the ECC unit 129 is detected from the data stored in a third page P3 of a second memory block BLK2. That is, the third page P3 of the second memory block BLK2 may be a read-failed page. The memory block management block 123 may select the memory block including the read-failed third page P3, that is, the second memory block BLK2, as a read-failed memory block and a test target block.

The memory block management block 123 may test the second memory block BLK2 selected as a block in which an uncorrectable error has occurred, while performing a read operation. The memory block management block 123 may determine whether the third page P3 has temporarily failed or it will fail again in subsequent operations, based on a test result. That is to say, the memory block management block 123 may determine whether the third page P3 has fundamentally or physically failed, based on a test result.

For instance, when the third page P3 read-succeeds in the test operation, the memory block management block 123 may determine that the third page P3 has temporarily read-failed. In other words, when a read success occurs in the third page P3 by the test operation, the memory block management block 123 may determine that the third page P3 has read-failed, for example, due to an environmental factor, and determine that the third page P3 and the second memory block BLK2 including the third page P3 have not failed fundamentally. For another instance, when the third page P3 read-fails even by the test operation, the memory block management block 123 may determine that the third page P3 will successively read-fail. Namely, when the third page P3 read-fails even by the test operation, the memory block management block 123 may determine that the third page P3 has read-failed, for example, due to a physical factor, and determine that the third page P3 and the second memory block BLK2 including the third page P3 have failed fundamentally.

The memory block management block 123 may manage or process whether to use a test target memory block, by using the memory block management table 127, based on a test result. For instance, when it is determined that the third page P3 has temporarily read-failed, the memory block management block 123 may process the second memory block BLK2 being the test target memory block, as a normal block, such that the second memory block BLK2 is used in subsequent operations. To this end, the memory block management block 123 may include the second memory block BLK2 in a usable memory block table, that is, a free block pool FBP. For another instance, when it is determined that the third page P3 will successively read-fail, the memory block management block 123 may process the second memory block BLK2 being the test target memory block, as a bad block, such that the second memory block BLK2 is not used permanently. To this end, the memory block management block 123 may include the second memory block BLK2 in a table of memory blocks to be excluded from address mapping, that is, a bad block pool BBP.

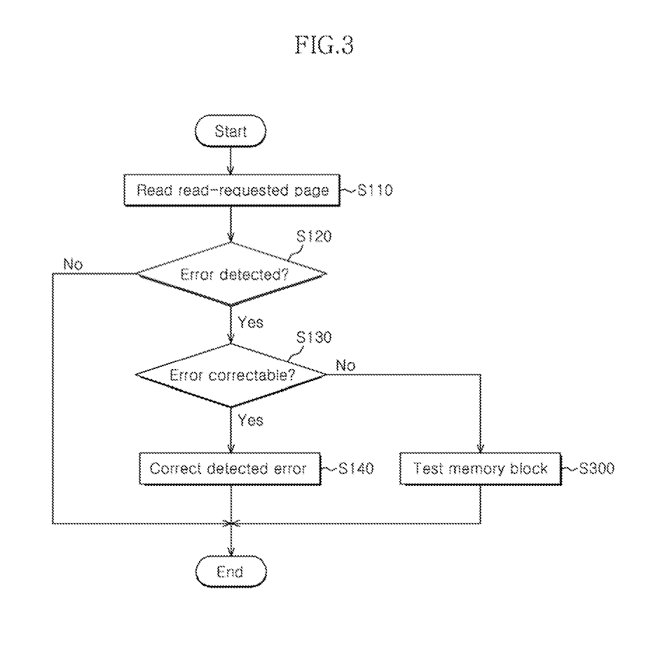

FIG. 3 is a flow chart to assist in the explanation of the operations of the data storage device which performs the memory block managing operation in accordance with an embodiment. The operations of the data storage device which performs in real time a test operation for a read-failed memory block will be described below with reference to FIG. 3.

At step S110, the control unit 121 may perform a read operation for the nonvolatile memory device 110, in response to a read request from the host device. That is to say, the control unit 121 may perform a read operation for a page corresponding to the address read-requested from the host device.

At step S120, the ECC unit 129 may determine whether an error is included in read data. When an error is not included in the read data, the read operation may be successfully ended. When an error is included in the read data, the process may proceed to step S130.

At step S130, the ECC unit 129 may determine whether the detected error is correctable. When the detected error is correctable, the process may proceed to step S140. At step S140, the ECC unit 129 may correct the error included in the read data. Then, the read operation may be successfully ended. When the detected error is uncorrectable, the process may proceed to step S300.

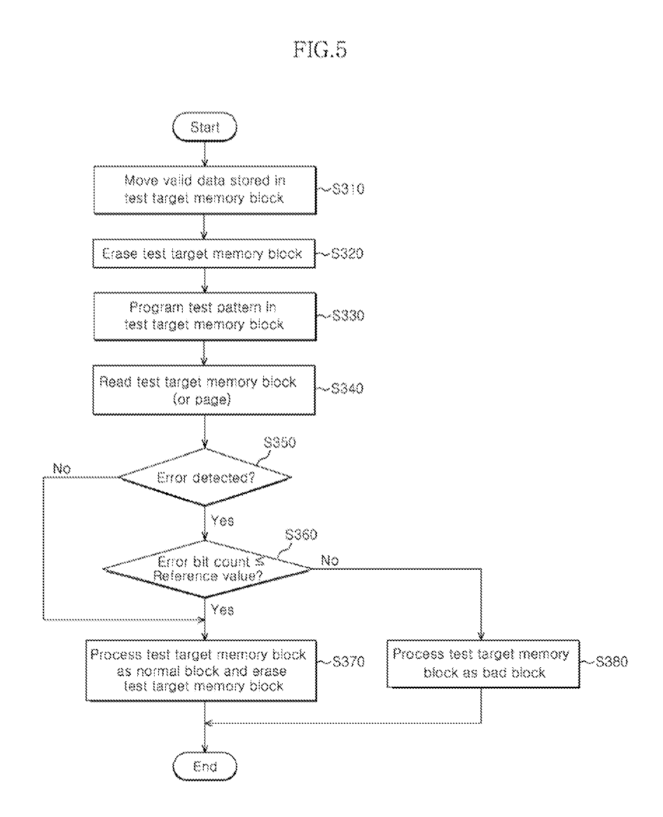

At step S300, the memory block management block 123 may test whether the memory block including the read-failed page is bad. A test operation for a memory block including a read-failed page will be described in detail with reference to the flow chart of FIG. 5.

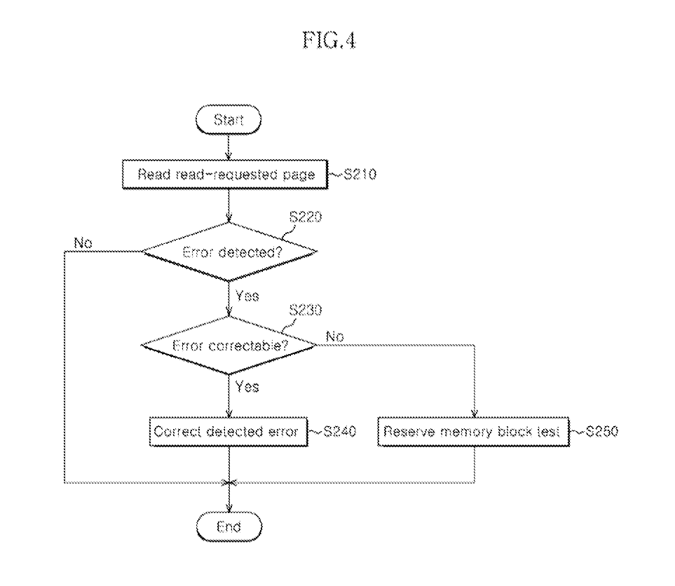

FIG. 4 is a flow chart to assist in the explanation of the operations of the data storage device which performs the memory block managing operation in accordance with another embodiment. The operations of the data storage device, which defers a test operation for a read-failed memory block to an idle time, will be described below with reference to FIG. 4.

At step S210, the control unit 121 may perform a read operation for the nonvolatile memory device 110, in response to a read request from the host device. That is to say, the control unit 121 may perform a read operation for a page corresponding to the address read-requested from the host device.

At step S220, the ECC unit 129 may determine whether an error is included in read data. When an error is not included in the read data, the read operation may be successfully ended. When an error is included in the read data, the process may proceed to step S230.

At step S230, the ECC unit 129 may determine whether the detected error is correctable. When the detected error is correctable, the process may proceed to step S240. At step S240, the ECC unit 129 may correct the error included in the read data. Then, the read operation may be successfully ended. When the detected error is uncorrectable, the process may proceed to step S250.

At step S250, the control unit 121 may select a memory block including a read-failed page (that is, a page in which an error-uncorrectable data is stored), and reserve a test for the selected memory block. In detail, the control unit 121 may manage information on the address of the read-failed page and the address of the memory block including the read-failed page (that is, a read-failed memory block), as test reservation information.

The memory block management block 123 may test the read-failed memory block based on the test reservation information during an idle time coming after a failed read operation is ended. The test operation for the read-failed memory block will be described below in detail with reference to the flow chart of FIG. 5.

FIG. 5 is a flow chart to assist in the explanation of a memory block testing operation shown in FIGS. 3 and 4. In describing FIG. 5, a memory block including a read-failed page, that is, a read-failed memory block will be referred to as a test target memory block.

At step S310, the memory block management block 123 may move the valid data stored in the test target memory block. In detail, the memory block management block 123 may copy the valid data stored in the test target memory block, in a free block allocated from the free block pool FBP, such that the valid data stored in the test target memory block are not lost due to a test operation. Also, the memory block management block 123 may update the address mapping information changed due to the copy of the valid data.

At step S320, the memory block management block 123 may erase the test target memory block.

At step S330, the memory block management block 123 may program a test pattern in the erased test target memory block. For instance, the memory block management block 123 may program the test pattern in only a read-failed page. For another instance, the memory block management block 123 may program the same test pattern in all pages of the test target memory block.

At step S340, the memory block management block 123 may read the test target memory block to read the programmed test pattern. For instance, when the test pattern is programmed in only the read-failed page, the memory block management block 123 may read only the read-failed page. For another instance, when the test pattern is programmed in all pages of the test target memory block, the memory block management block 123 may read the plurality of pages including the read-failed page. For example, the memory block management block 123 may read all pages of the test target memory block. For example, the memory block management block 123 may read the read-failed page and pages physically adjacent to the read-failed page.

At step S350, the memory block management block 123 may determine whether an error is included in read data, through the ECC unit 129. When an error is not included in the read data, the process may proceed to step S370. Step S370 will be described later in detail. When an error is included in read data, the process may proceed to step S360.

At step S360, the memory block management block 123 may determine whether the count of the error bits included in the read data is equal to or smaller than a reference value. The reference value may be changed depending on the count of pages of the test target memory block which are read at step S340. For instance, a reference value when the plurality of pages including the read-failed page are read may be larger than a reference value when only the read-failed page is read.

When the count of the error bits is equal to or smaller than the reference value, the process may proceed to step S370. At step S370, the memory block management block 123 may process the test target memory block as a normal block, and erase the test target memory block. In other words, when a test for the test target memory block produces a result corresponding to “error not found” or “allowable error found”, the memory block management block 123 may determine that the test target memory block does not correspond to a fundamental failure, and may process the test target memory block as a normal block. To this end, the memory block management block 123 may erase the test target memory block programmed with the test pattern, and include the test target memory block in the free block pool FBP.

Conversely, when the count of the error bits exceeds the reference value, the process may proceed to step S380. At step S380, the memory block management block 123 may process the test target memory block as a bad block. Namely, when a test for the test target memory block produces a result corresponding to “unallowable error found”, the memory block management block 123 may determine that the test target memory block corresponds to a fundamental failure, and may process the test target memory block as a bad block. To this end, the memory block management block 123 may include the test target memory block in the bad block pool BBP.

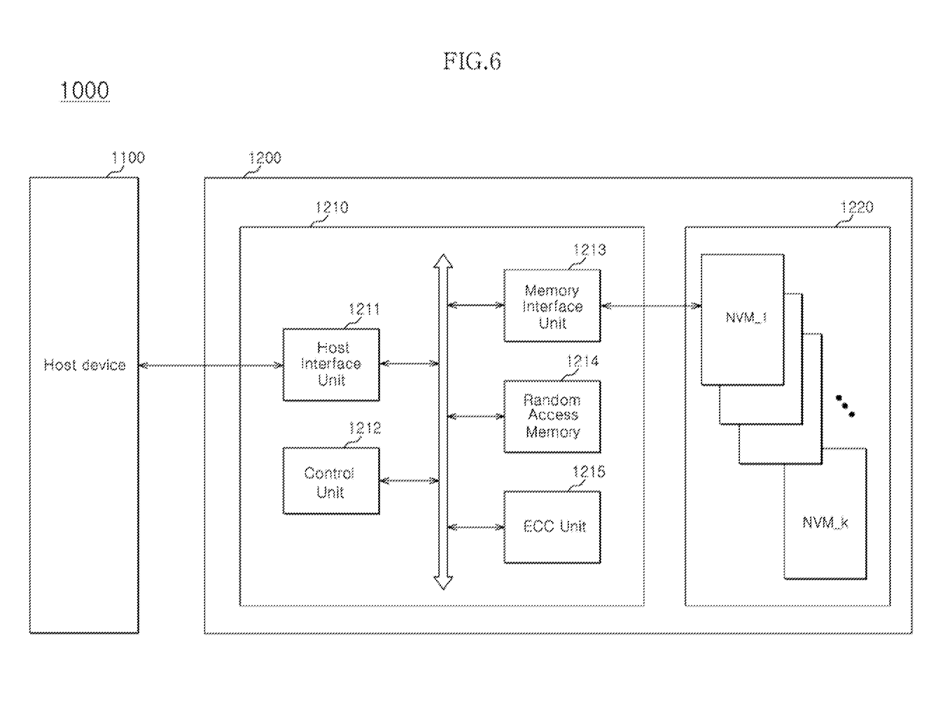

FIG. 6 is a block diagram illustrating a data processing system including a data storage device in accordance an embodiment. Referring to FIG. 6, a data processing system 1000 may include a host device 1100 and a data storage device 1200.

The data storage device 1200 may include a controller 1210, and a nonvolatile memory device 1220. The data storage device 1200 may be used by being electrically coupled to the host device 1100 such as a mobile phone, an MP3 player, a laptop computer, a desktop computer, a game player, a TV, an in-vehicle infotainment system, and so forth. The data storage device 1200 may be referred to as a memory system.

The controller 1210 may be configured to access the nonvolatile memory device 1220 in response to a request from the host device 1100. For example, the controller 1210 may be configured to control the read, program or erase operations of the nonvolatile memory device 1220. The controller 1210 may be configured to drive firmware or software for controlling the nonvolatile memory device 1220.

The controller 1210 may include a host interface unit 1211, a control unit 1212, a memory interface unit 1213, a random access memory 1214, and an error correction code (ECC) unit 1215.

The control unit 1212 may be configured to control the general operations of the controller 1210 in response to a request from the host device 1100. Although not shown, the control unit 1212 may include the memory block management block 123 shown in FIG. 1, and perform the function of the memory block management block 123.

The random access memory 1214 may be used as the working memory of the control unit 1212. The random access memory 1214 may be used as a buffer memory which temporarily stores the data read from the nonvolatile memory device 1220 or the data provided from the host device 1100.

The host interface unit 1211 may be configured to interface the host device 1100 and the controller 1210. For example, the host interface unit 1211 may be configured to communicate with the host device 1100 through one of various interface protocols such as a universal serial bus (USB) protocol, a universal flash storage (UFS) protocol, a multimedia card (MMC) protocol, a peripheral component interconnection (PCI) protocol, a PCI express (PCI-E) protocol, a parallel advanced technology attachment (PATA) protocol, a serial advanced technology attachment (SATA) protocol, a small computer system interface (SCSI) protocol, and a serial attached SCSI (SAS) protocol.

The memory interface unit 1213 may be configured to interface the controller 1210 and the nonvolatile memory device 1220. The memory interface unit 1213 may be configured to provide commands and addresses to the nonvolatile memory device 1220. Furthermore, the memory interface unit 1213 may be configured to exchange data with the nonvolatile memory device 1220.

The error correction code unit 1215 may be configured to detect an error of the data read from the nonvolatile memory device 1220. Also, the error correction code unit 1215 may be configured to correct the detected error when the detected error is within a correctable range.

The nonvolatile memory device 1220 may be used as the storage medium of the data storage device 1200. The nonvolatile memory device 1220 may include a plurality of nonvolatile memory chips (or dies) NVM_1 to NVM_k.

The controller 1210 and the nonvolatile memory device 1220 may be manufactured as any one of various data storage devices. For example, the controller 1210 and the nonvolatile memory device 1220 may be integrated into one semiconductor device and may be manufactured as any one of a multimedia card in the form of an MMC, an eMMC, an RS-MMC and a micro-MMC, a secure digital card in the form of an SD, a mini-SD and an micro-SD, a universal serial bus (USB) storage device, a universal flash storage (UFS) device, a personal computer memory card international association (PCMCIA) card, a compact flash (CF) card, a smart media card, a memory stick, and so forth.

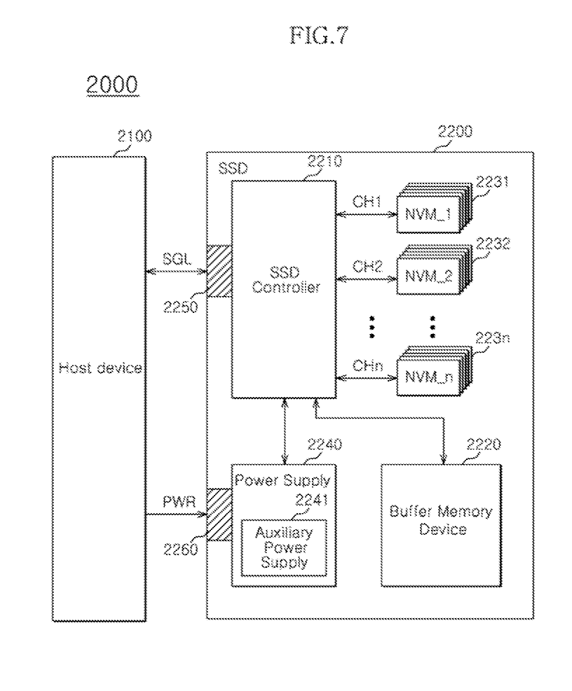

FIG. 7 is a block diagram illustrating a data processing system including a solid state drive (SSD) in accordance with an embodiment. Referring to FIG. 7, a data processing system 2000 may include a host device 2100 and a solid state drive (SSD) 2200.

The SSD 2200 may include an SSD controller 2210, a buffer memory device 2220, nonvolatile memory devices 2231 to 223n, a power supply 2240, a signal connector 2250, and a power connector 2260.

The SSD 2200 may operate in response to a request from the host device 2100. In other words, the SSD controller 2210 may be configured to access the nonvolatile memory devices 2231 to 223n in response to a request from the host device 2100. For example, the SSD controller 2210 may be configured to control the read, program and erase operations of the nonvolatile memory devices 2231 to 223n.

The buffer memory device 2220 may be configured to temporarily store data in the nonvolatile memory devices 2231 to 223n. Further, the buffer memory device 2220 may be configured to temporarily store data which are read from the nonvolatile memory devices 2231 to 223n. The data temporarily stored in the buffer memory device 2220 may be transmitted to the host device 2100 or the nonvolatile memory devices 2231 to 223n under the control of the SSD controller 2210.

The nonvolatile memory devices 2231 to 223n may be used as storage media of the SSD 2200. The nonvolatile memory devices 2231 to 223n may be electrically coupled to the SSD controller 2210 through a plurality of channels CH1 to CHn, respectively. One or more nonvolatile memory devices may be electrically coupled to one channel. The nonvolatile memory devices electrically coupled to one channel may be electrically coupled to the same signal bus and data bus.

The power supply 2240 may be configured to provide power PWR inputted through the power connector 2260, to the inside of the SSD 2200. The power supply 2240 may include an auxiliary power supply 2241. The auxiliary power supply 2241 may be configured to supply power so as to allow the SSD 2200 to be properly terminated when a sudden power-off occurs. The auxiliary power supply 2241 may include super capacitors capable of being charged with the power PWR.

The SSD controller 2210 may exchange a signal SGL with the host device 2100 through the signal connector 2250. The signal SGL may include a command, an address, data, and so forth. The signal connector 2250 may be configured for various protocols such as parallel advanced technology attachment (PATA), serial advanced technology attachment (SATA), small computer system interface (SCSI), serial attached SCSI (SAS), peripheral component interconnection (PCI) and PCI express (PCI-E) protocols, depending on the interface scheme between the host device 2100 and the SSD 2200.

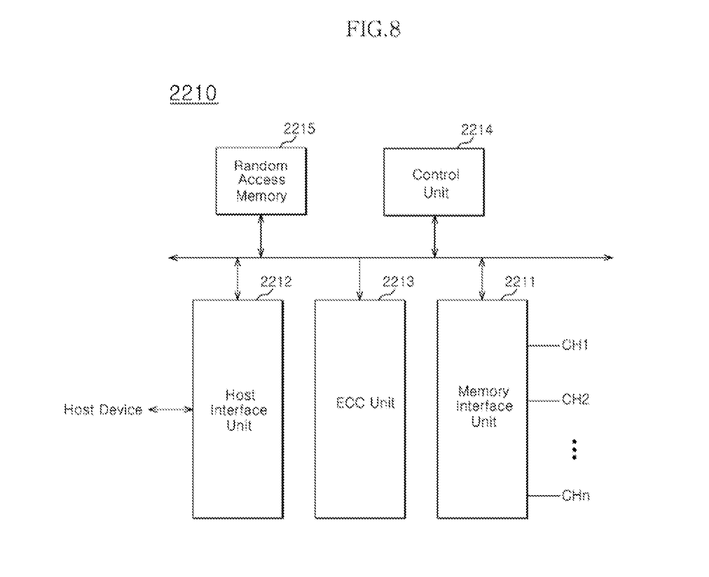

FIG. 8 is a block diagram illustrating an example of the SSD controller shown in FIG. 7. Referring to FIG. 8, the SSD controller 2210 may include a memory interface unit 2211, a host interface unit 2212, an error correction code (ECC) unit 2213, a control unit 2214, and a random access memory 2215.

The memory interface unit 2211 may be configured to provide a control signal such as a command and an address for the nonvolatile memory devices 2231 to 223n. Moreover, the memory interface unit 2211 may be configured to exchange data with the nonvolatile memory devices 2231 to 223n. The memory interface unit 2211 may scatter the data transmitted from the buffer memory device 2220 to the channels CH1 to CHn, under the control of the control unit 2214. Furthermore, the memory interface unit 2211 may transmit the data read from the nonvolatile memory devices 2231 to 223n to the buffer memory device 2220, under the control of the control unit 2214.

The host interface unit 2212 may be configured to provide interfacing with the SSD 2200 in correspondence with the protocol of the host device 2100. For example, the host interface unit 2212 may be configured to communicate with the host device 2100 through one of parallel advanced technology attachment (PATA), serial advanced technology attachment (SATA), small computer system interface (SCSI), serial attached SCSI (SAS), peripheral component interconnection (PCI) and PCI express (PCI-E) protocols. In addition, the host interface unit 2212 may perform a disk emulating function of supporting the host device 2100 to recognize the SSD 2200 as a hard disk drive (HDD).

The ECC unit 2213 may be configured to generate parity bits based on the data transmitted to the nonvolatile memory devices 2231 to 223n. The generated parity bits may be stored along with data in the nonvolatile memory devices 2231 to 223n. The ECC unit 2213 may be configured to detect an error of the data read from the nonvolatile memory devices 2231 to 223n. When the detected error is within a correctable range, the ECC unit 2213 may be configured to correct the detected error.

The control unit 2214 may be configured to analyze and process the signal SGL inputted from the host device 2100. The control unit 2214 may control the general operations of the SSD controller 2210 in response to a request from the host device 2100. The control unit 2214 may control the operations of the buffer memory device 2220 and the nonvolatile memory devices 2231 to 223n based on firmware for driving the SSD 2200. The random access memory 2215 may be used as a working memory for driving the firmware.

Although not shown, the control unit 2214 may include the memory block management block 123 shown in FIG. 1, and perform the function of the memory block management block 123.

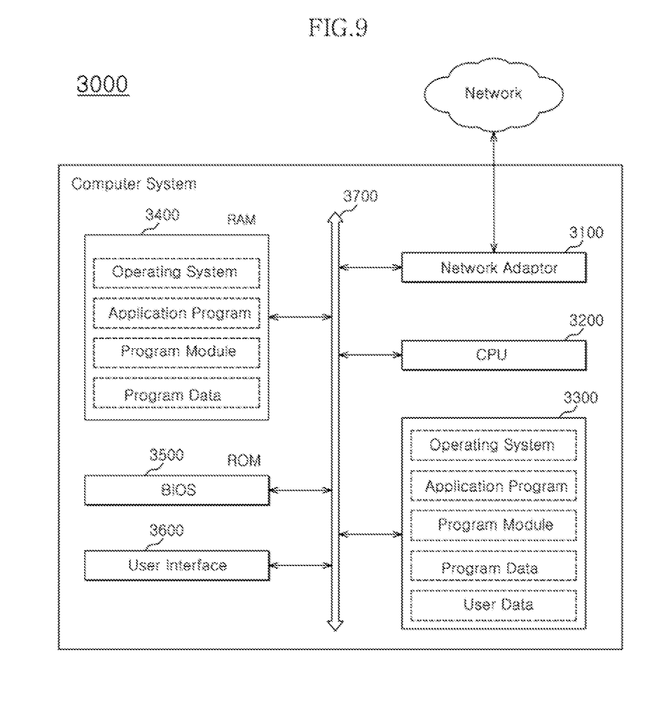

FIG. 9 is a block diagram illustrating a computer system in which a data storage device is mounted, in accordance with an embodiment. Referring to FIG. 9, a computer system 3000 includes a network adaptor 3100, a central processing unit 3200, a data storage device 3300, a RAM 3400, a ROM 3500 and a user interface 3600, which are electrically coupled to a system bus 3700. The data storage device 3300 may be configured by the data storage device 100 shown in FIG. 1, the data storage device 1200 shown in FIG. 6 or the SSD 2200 shown in FIG. 7.

The network adaptor 3100 provides interfacing between the computer system 3000 and external networks. The central processing unit 3200 performs general operations for driving an operating system or an application program loaded on the RAM 3400.

The data storage device 3300 stores general data necessary in the computer system 3000. For example, an operating system for driving the computer system 3000, an application program, various program modules, program data and user data are stored in the data storage device 3300.

The RAM 3400 may be used as a working memory device of the computer system 3000. Upon booting, the operating system, the application program, the various program modules and the program data necessary for driving programs, which are read from the data storage device 3300, are loaded on the RAM 3400. A BIOS (basic input/output system), which is activated before the operating system is driven, is stored in the ROM 3500. Information exchange between the computer system 3000 and a user is implemented through the user interface 3600.

While various embodiments have been described above, it will be understood to those skilled in the art that the embodiments described are examples only. Accordingly, the operating method of a data storage device described herein should not be limited based on the described embodiments.

What is claimed is:

1. An operating method of a data storage device, comprising:
selecting a memory block including a page in which an uncorrectable error occurs in a read operation;
testing whether the selected memory block corresponds to a fail;
including the selected memory block in a free block table when the selected memory block corresponds to a success as a result of the testing; and
including the selected memory block in a bad block table when the selected memory block corresponds to the fail as a result of the testing.

2. The operating method according to claim 1, wherein the testing of whether the selected memory block corresponds to the fail comprises:
programming a test pattern in the selected memory block, and reading the selected memory block;
comparing a count of error bits included in data read from the selected memory block and a reference value; and
determining whether the selected memory block corresponds to the fail, based on a result of the comparing.

3. The operating method according to claim 2, wherein, when the count of the error bits included in the read data is equal to or smaller than the reference value, it is determined that the selected memory block corresponds to the success.

4. The operating method according to claim 2, wherein, when the count of the error bits included in the read data exceeds the reference value, it is determined that the selected memory block corresponds to the fail.

5. The operating method according to claim 2, wherein the reading of the selected memory block comprises:
reading only the page in which the uncorrectable error occurs.

6. The operating method according to claim 2, wherein the reading of the selected memory block comprises:
reading a plurality of pages including the page in which the uncorrectable error occurs.

7. The operating method according to claim 2, wherein the testing of whether the selected memory block corresponds to the fail further comprises, before the programming of the test pattern:
copying valid data stored in the selected memory block; and
erasing the selected memory block.

8. The operating method according to claim 1, wherein the testing of whether the selected memory block corresponds to the fail is performed during an idle time.

9. An operating method of a data storage device, comprising:
determining whether an error is correctable when the error is detected in data read from a read-requested page;
selecting a memory block which includes the page, when it is determined that the error is uncorrectable; and
managing reservation information for the selected memory block, and reserving a test for the selected memory block.

10. The operating method according to claim 9, further comprising:
testing the selected memory block, based on the reservation information, during an idle time.

11. The operating method according to claim 10, wherein the reservation information includes address information of the selected memory block and address information of the page.

12. The operating method according to claim 10, wherein the testing of the selected memory block comprises:
programming a test pattern in the selected memory block, and reading the selected memory block;
comparing a count of error bits included in data read from the selected memory block and a reference value; and
determining whether to use the selected memory block based on a result of the comparing.

13. The operating method according to claim 12, wherein the selected memory block is included in a free block table to be used in a subsequent operation, when the count of the error bits included in the read data is equal to or smaller than the reference value.

14. The operating method according to claim 12, wherein the selected memory block is included in a bad block table that is never to be used again, when the count of the error bits included in the read data exceeds the reference value.

15. The operating method according to claim 12, wherein the reading of the selected memory block comprises:
reading only the page.

16. The operating method according to claim 12, wherein the reading of the selected memory block comprises:
reading the page and pages which are physically adjacent to the page.

17. The operating method according to claim 9, further comprising:
detecting whether the error occurs in the data read form the read-requested page.
